(19) United States
(12) Patent Application Publication
(10) Pub. No.: US 2020/0166034 A1
(43) Pub. Date: May 28, 2020

(54) ELECTRONIC COMPRESSOR

(71) Applicant: Hanon Systems, Daejeon (KR)

(72) Inventors: Chan Song, Daejeon (KR); Tae Hyeong Kim, Daejeon (KR); Seung Hwan Shin, Daejeon (KR); Eun Seok Kang, Daejeon (KR)

(21) Appl. No.: 16/682,215

(22) Filed: Nov. 13, 2019

(30) Foreign Application Priority Data
Nov. 22, 2018 (KR) 10-2018-0145171

(51) Int. Cl. F04C 29/04; H01R 9/16; H02K 11/33; H02K 5/22; F04C 23/02; F04B 39/12; H05K 1/02

(52) U.S. Cl. CPC F04C 29/047; H01R 9/16; H02K 11/33; H02K 5/22; F04C 2240/30; F04B 39/121; H05K 1/02; F04C 2240/40; F04C 2240/808; F04C 23/02

(57) ABSTRACT

An electric compressor, which may secure a space part between a mechanism part on which a receiving element is mounted and a printed circuit board (PCB), thereby reducing a package, and freely disposing an element, and the present disclosure provides an electric compressor, which includes an inverter housing, a printed circuit board (PCB) coupled to the inverter housing, and a mechanism part provided between the inverter housing and the printed circuit board and on which a receiving element is mounted, and a space part is secured between the printed circuit board and the mechanism part.

### CROSS-REFERENCE TO RELATED APPLICATIONS

This patent application claims priority to Korean Patent Application No. 10-2018-0145171 filed on Nov. 22, 2018, the disclosure of which is incorporated herein by reference in its entirety.

### FIELD

The present disclosure relates to an electric compressor, and more particularly, to an electric compressor, which may secure a space part between a mechanism part on which a receiving element is mounted and a printed circuit board (PCB), thereby reducing a package, and freely disposing an element.

### BACKGROUND

Generally, a compressor used in an air-conditioning system for a vehicle sucks the refrigerant completely evaporated from an evaporator and transfers it to a condenser at the high-temperature and high-pressure state that are easy to be liquefied. Such a compressor includes a reciprocating type for performing compression while performing a reciprocating motion, and a rotary type for performing compression while performing a rotational motion, as a configuration of actually compressing refrigerant. The rotary compressor includes a mechanical type in which rotation is performed by using an engine as a drive source, and an electric type in which a motor is used as a drive source.

In the electric compressor, a rotational speed is controlled by an inverter, and the inverter is provided as a type in which various circuit elements such as a switching element (Insulated Gate Bipolar Transistor; IGBT) and a capacitor are mounted on a Printed Circuit Board (PCB).

Reviewing a conventional inverter with reference to FIG. 1, a mechanism part 30 equipped with a capacitor 20 is fixed on the printed circuit board 10. For this purpose, a space part for installing the mechanism part 30 on the printed circuit board 10 is required conventionally.

Accordingly, there is a problem in that a configuration in which it is difficult to reduce the package of the inverter, the space on the printed circuit board 10 is limited, and a Surface Mounted Device (SMD) mounted on the printed circuit board 10 is disposed is not free.

Related Art Document. Patent Document. Patent Document 1) Korean Patent Laid-Open Publication No. 10-2015-0033060 (published on Apr. 1, 2015).

### SUMMARY

An object of the present disclosure is to provide an electric compressor, which may secure a space part between a mechanism part on which a receiving element is mounted and a printed circuit board (PCB), thereby reducing a package, and freely disposing an element.

The object of the present disclosure is not limited to the object described above, and other objects not mentioned may be clearly understood by those skilled in the art to which the present disclosure pertains from the following description.

The present disclosure for achieving the object provides an electric compressor including an inverter housing, a printed circuit board (PCB) coupled to the inverter housing, a mechanism part provided between the inverter housing and the printed circuit board and on which a receiving element is mounted, and a spacing means for forming a space part between the printed circuit board and the mechanism part.

According to an embodiment of the present disclosure, the spacing means may include one or more ribs protruded and extended from the mechanism part toward the printed circuit board so that the mechanism part and the printed circuit board may be maintained in a state spaced apart from each other.

According to an embodiment of the present disclosure, at least one of the ribs may be a lead inserting part into which a lead of the receiving element is inserted.

According to an embodiment of the present disclosure, the lead of the receiving element may be soldered to the printed circuit board through the lead inserting part.

According to an embodiment of the present disclosure, the lead inserting part may be provided at the position corresponding to the position of the lead of the receiving element mounted on the mechanism part.

According to an embodiment of the present disclosure, the mechanism part may be coupled to the inverter housing.

According to an embodiment of the present disclosure, silicone may be applied to the contact surface between the mechanism part and the inverter housing.

According to an embodiment of the present disclosure, the mechanism part may be coupled to the printed circuit board.

According to an embodiment of the present disclosure, a portion of the receiving element may be protruded from the mechanism part toward the inverter housing side to contact the inverter housing.

According to an embodiment of the present disclosure, a fastening means may be fixed to the inverter housing by penetrating the printed circuit board.

According to an embodiment of the present disclosure, a fastening means may be penetrated and inserted into at least one of the ribs from the printed circuit board.

According to an embodiment of the present disclosure, the receiving element may be a passive element.

According to an embodiment of the present disclosure, the receiving element may be a capacitor.

According to an embodiment of the present disclosure, a surface mounted device (SMD) may be disposed on the printed circuit board in the space part between the printed circuit board and the mechanism part.

According to an embodiment of the present disclosure, the distance (h1) between the printed circuit board and the mechanism part may be formed larger than the maximum height (h2) of the surface mounted device protruded from the printed circuit board in the space part.

According to the present disclosure, it is possible to secure a space part between the mechanism part on which the receiving element is mounted and the printed circuit board, thereby disposing the surface mounted device (SMD) mounted on the printed circuit board on the space part. That is, the space in which the surface mounted device may be disposed on the printed circuit board is not limited, thereby freely disposing the element.

Further, since a separate space is not required for installing the mechanism part on which the receiving element is mounted on the printed circuit board, it is possible to reduce the package size of the inverter.

It should be understood that the effects of the present disclosure are not limited to the effects described above, and include all effects that may be inferred from the detailed description of the disclosure or the configuration of the disclosure recited in the claims.

### DRAWINGS

FIG. 1 is a perspective diagram showing a conventional inverter.

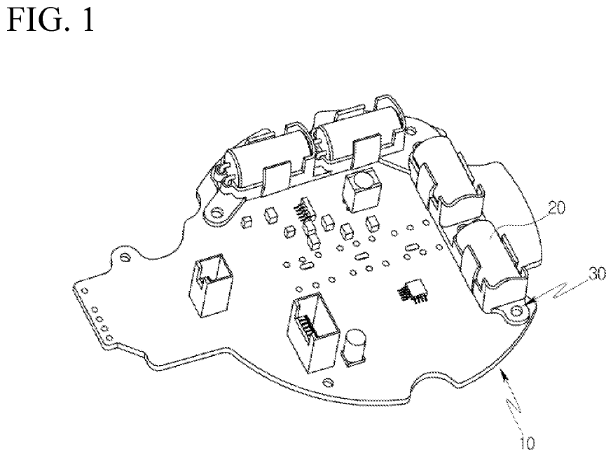

FIG. 2 is a cross-sectional diagram showing an electric compressor according to an embodiment of the present disclosure.

FIG. 3 is a cross-sectional diagram schematically showing an inverter according to a first embodiment of the present disclosure.

FIG. 4 is a plane diagram of FIG. 3.

FIG. 5 is a cross-sectional diagram schematically showing an inverter according to a second embodiment of the present disclosure.

FIG. 6 is a plane diagram of FIG. 5.

FIG. 7 is a cross-sectional diagram schematically showing an inverter according to a third embodiment of the present disclosure.

FIG. 8 is a plane diagram of FIG. 7.

FIG. 9 is a cross-sectional diagram schematically showing an inverter according to a fourth embodiment of the present disclosure.

FIG. 10 is a cross-sectional diagram schematically showing an inverter according to a fifth embodiment of the present disclosure.

FIG. 11 is a cross-sectional diagram schematically showing an inverter according to a sixth embodiment of the present disclosure.

### DETAILED DESCRIPTION

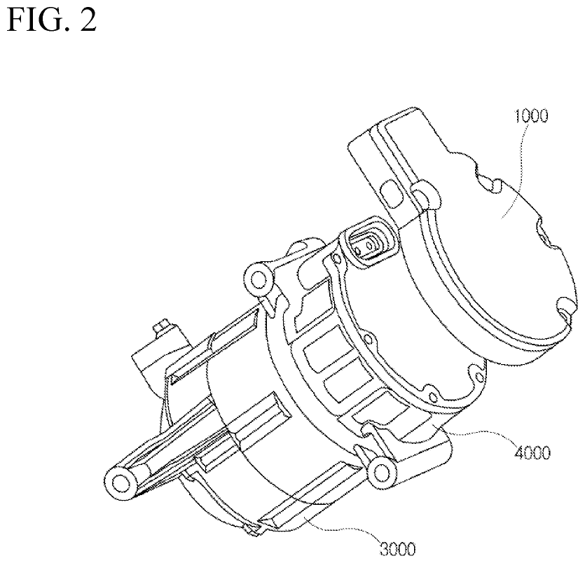

Hereinafter, preferred embodiments of an electric compressor of the present disclosure will be described with reference to FIGS. 2 to 11.

Further, the following terms are terms defined considering the functions of the present disclosure, and this may be changed according to the intention or the custom of a user and an operator, and the following embodiments do not limit the claims but are merely illustrative of the components recited in the claims of the present disclosure.

In order to clearly illustrate the present disclosure, parts not related to the description have been omitted, and the same reference numerals are denoted for the same or similar components throughout the specification. Throughout the specification, when an element “comprises” a component, it means that it may further include other components, rather than excluding other components unless specifically stated otherwise.

First, reviewing an electric compressor according to an embodiment of the present disclosure with reference to FIG. 2, an electric compressor mainly includes a compressor part 3000 for compressing refrigerant, a motor part 4000 for driving the compressor 3000 and an inverter 1000 for adjusting the amount of compression of the refrigerant by controlling the rotational speed of the motor part 4000.

The motor part 4000 is a part for generating the rotational power of the compressor 3000, and composed of a motor received in a motor part housing, and the motor includes a stator installed along the inner circumferential surface of the motor part housing, and a rotor that rotates inside the stator.

The stator is a kind of electromagnetic, and composed of a stator core fixedly mounted on the inner circumferential surface of the motor part housing by press-fitting, etc., and a coil bundle wound around the stator core, and when a current flows through the coil bundle, a magnetic field is formed on the stator.

The rotor is rotatably inserted into the central hole of the stator core, and composed of a rotary shaft that is disposed lengthily along the central axis, and a permanent magnet attached to the outer circumferential surface of the rotary shaft.

Accordingly, when the stator is excited, the rotor is driven to rotate by interaction with the stator according to the driving principle of the motor, and the rotational driving force is transferred to the compression part 3000 connected to the rotary shaft.

The compression part 3000 is a part of compressing refrigerant by rotating by receiving the rotational driving force generated by the motor part 4000, and connected to one end of the rotary shaft.

The compression part 3000 includes a compression part housing coupled to one side of the motor part housing, an orbiting scroll rotatably mounted inside the compression part housing, and a fixed scroll for compressing refrigerant by pairing with the orbiting scroll, and compresses the refrigerant by the relative rotation of the orbiting scroll and the fixed scroll.

However, the compression part 3000 and the motor part 4000 are not limited to the above-described embodiments, and the compression part may be any structure for compressing the refrigerant, and the motor part may be any structure for driving the compression part.

The inverter part 1000 is a part for controlling an operation of the motor part 4000, and converts DC power into AC power and is electrically connected to the stator of the motor part 4000 to demagnetize the stator, and accordingly, the rotational speed of the motor may be controlled by rotating or stopping the rotor.

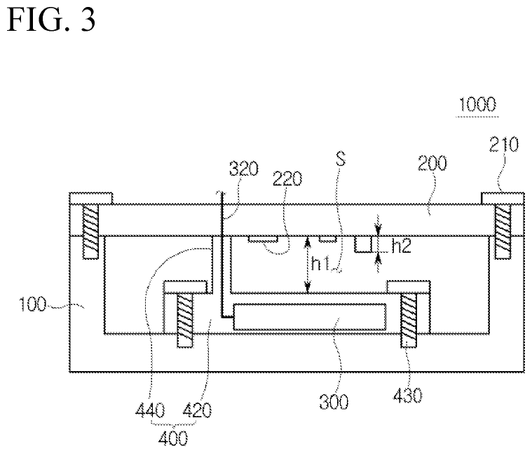

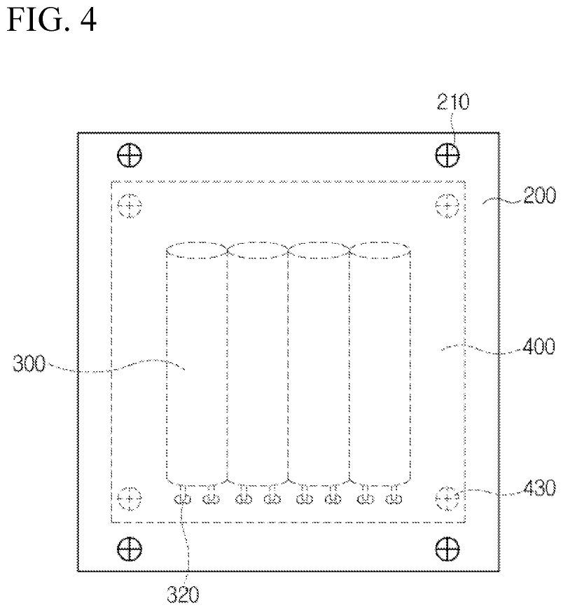

Hereinafter, the inverter 1000 according to a first embodiment of the present disclosure will be described with reference to FIGS. 3 and 4.

The inverter 1000 according to the first embodiment of the present disclosure mainly includes an inverter housing 100, a printed circuit board (PCB) 200 coupled to the inverter housing 100, and a mechanism part 400 on which a receiving element 300 is mounted. At this time, the mechanism part 400 is provided between the inverter housing 100 and the printed circuit board 200, and a space part (S) between the printed circuit board 200 and the mechanism part 400 is formed by a spacing means.

Specifically, the inverter housing 100 has a E -shape with the upper portion opened, and the printed circuit board 200 is coupled to the upper portion of the inverter housing 100. At this time, as a separate fastening means, for example, a bolt 210 is fixed to the inverter housing 100 by penetrating the print circuit board 200, the printed circuit board 200 may be coupled to the upper portion of the inverter housing 100.

Here, the inverter housing 100 may correspond to a housing constituting the outer shape of the inverter 1000 and also correspond to a carrier separately provided from the housing constituting the outer shape thereof

In this embodiment, the mechanism part 400 on which the receiving element 300 is mounted is coupled to the inverter housing 100. That is, as shown in FIG. 3, the mechanism part 400 is provided between the inverter housing 100 and the printed circuit board 200, and coupled to the inverter housing 100 in a state spaced apart from the printed circuit board 200.

Specifically, the mechanism part 400 includes a base 420 mounted with the receiving element 300 and formed of a rectangular plate, and as a bolt 430 is fixed to the inverter housing 100 by penetrating the base 420, the mechanism part 400 may be coupled to the inverter housing 100. The receiving element 300 may be a passive element such as a capacitor or an IC element. However, the present disclosure is not limited thereto and the mechanism part 400 may also be supported by contacting between the printed circuit board 200 and the inverter housing 100 by a spacing means described later without a separate fastening means such as a bolt.

At this time, silicone may be applied to the contact surface between the mechanism part 400 and the inverter housing 100 as necessary in order to enhance the coupling strength.

Further, a lead 320 of the receiving element 300 may be inserted as a spacing means, and a lead inserting part 440 protruded and extended from the mechanism part 400 toward the printed circuit board 200 may be provided.

In this embodiment, the lead inserting part 440 is protruded and extended from the base 420 to contact the printed circuit board 200, and the lead 320 of the receiving element is soldered to the printed circuit board 200. The lead inserting part 440 may be configured to insulate the lead 320 of the receiving element, and may serve to support the printed circuit board 200.

As shown in FIG. 4, in this embodiment, a plurality of receiving elements 300 are mounted on the mechanism part 400, and the plurality of receiving elements 300 are disposed so that the leads 320 of the receiving elements are all positioned in the same direction. At this time, the lead inserting part 440 may also be provided at the position corresponding to the position of the lead 320 of the receiving element on the base 420.

As described above, as the receiving element 300 is connected to the printed circuit board 200 and at the same time, the space part (S) is secured between the printed circuit board 200 and the mechanism part 400, a separate space for installing the mechanism part 400 for mounting the receiving element 300 may not be required on the printed circuit board 200, thereby reducing the package of the inverter.

Further, as exemplarily shown in FIG. 3, various surface mounted devices (SMD) 220 mounted on the printed circuit board 200 may also be disposed on the space part (S), thereby not limiting the space in which the surface mounted device 220 may be disposed on the printed circuit board 200 and freely disposing the element.

At this time, the distance (h1) between the printed circuit board 200 and the mechanism part 400 is preferably formed larger than the maximum height (h2) of the surface mounted device 220 protruded from the printed circuit board 200 in the space part (S) in order to freely dispose the element.

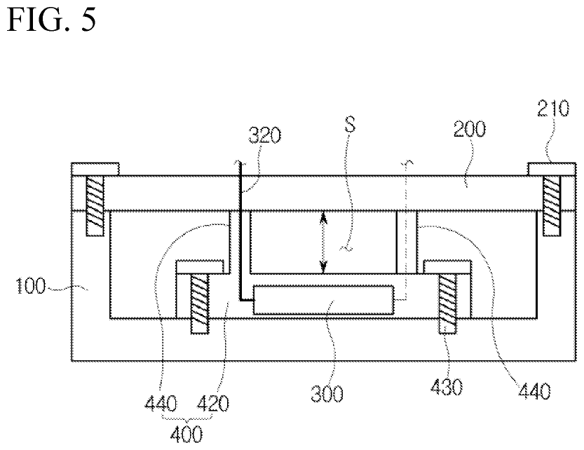

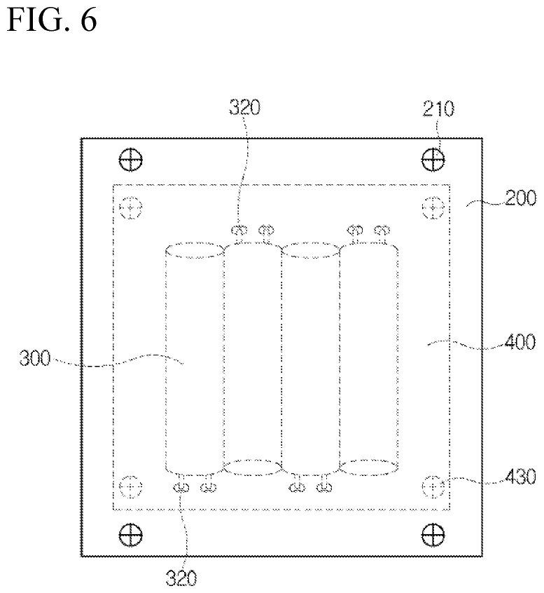

Next, referring to FIGS. 5 and 6, an inverter according to a second embodiment of the present disclosure is only different from the structure of disposing the inverter and the receiving element 300 and the structure of disposing the lead inserting part 440 therefrom according to the above-described first embodiment, and the remainder is all the same, such that only different parts will be described.

In this embodiment, a plurality of receiving elements 300 are mounted on the mechanism part 400, and the plurality of receiving elements 300 are disposed so that the leads 320 of the receiving elements adjacent to each other are disposed in the direction opposite to each other. Correspondingly, the lead inserting part 440 is also provided at both sides at the position where the lead 320 of the receiving element is disposed.

However, the present disclosure is not limited thereto, and a plurality of the receiving elements 300 may be freely disposed in the mechanism part 400, and the lead insertion part 440 may be provided by corresponding to the position of the lead 320 of the receiving element.

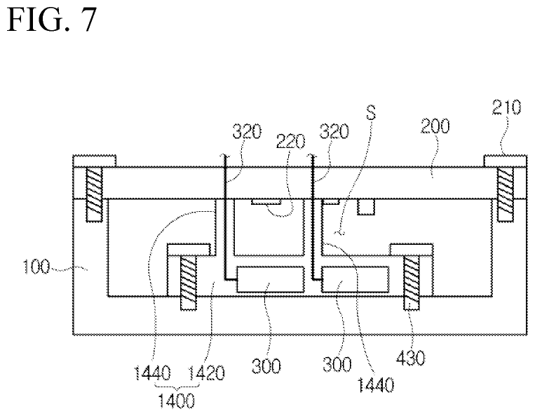

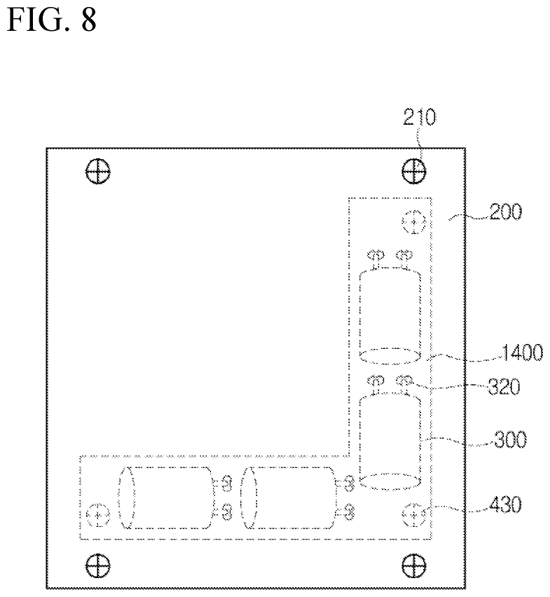

Further, referring to FIGS. 7 and 8, an inverter according to a third embodiment of the present disclosure is only different from the structure of disposing the inverter and the receiving element 300 and the structure of a mechanism part 1400 therefrom according to the above-described first embodiment, and the remainder is all the same, such that only different parts will be described.

In this embodiment, a plurality of receiving elements 300 are mounted on the mechanism part 1400, and the plurality of receiving elements 300 are disposed in a line so as to form a ┐ shape. Accordingly, a base 1420 of the mechanism part 1400 may also be formed in the ┐ shape.

Specifically, as shown in FIG. 8, the plurality of receiving elements 300 are disposed by two in a row to be 90°, and the lead 320 of each of the receiving elements is disposed in the same direction. Correspondingly, a lead insertion part 1440 of the mechanism part 1400 is also provided at the position corresponding to the position of the lead 320 of each of the receiving elements on the base 1420.

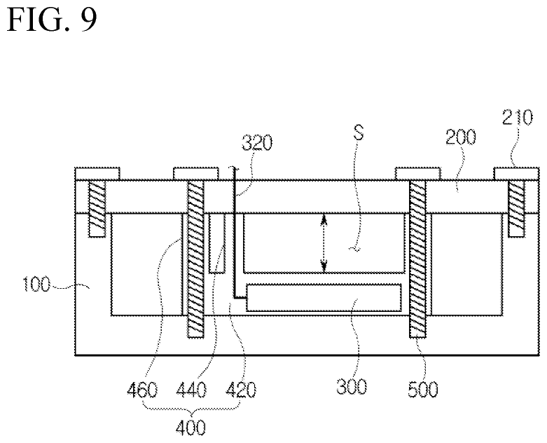

Next, an inverter according to a fourth embodiment of the present disclosure will be described with reference to FIG. 9.

The inverter according to the fourth embodiment of the present disclosure includes all the configurations of the inverter according to the above-described first embodiment, and further includes a rib 460. Hereinafter, only different part will be mainly described.

In this embodiment, the rib 460 protruded and extended from the mechanism part 400 toward the printed circuit board 200 may be further provided so as to contact and support the printed circuit board 200 as a spacing means.

The rib 460 may be protruded and extended from the base 420 in parallel with the lead inserting part 440 to contact the printed circuit board 200, and may support the printed circuit board 200 so that the spacing distance between the base 420 and the printed circuit board 200 may be maintained.

Further, a separate fastening means fixed to the inverter housing 100 may be penetrated and inserted into the rib 460. Specifically, in this embodiment, a bolt inserting hole is formed to penetrate the rib 460, and as the bolt 500 is fixed to the inverter housing 100 by penetrating the printed circuit board 200 and the bolt inserting hole of the rib, the printed circuit board 200, the mechanism part 400, and the inverter housing 100 may be integrally coupled.

Accordingly, the same effects as those of the inverter according to the first embodiment may be obtained, and at the same time, the printed circuit board 200, the mechanism part 400, and the inverter housing 100 may be integrally coupled, thereby enhancing the coupling strength and implementing a stable structure.

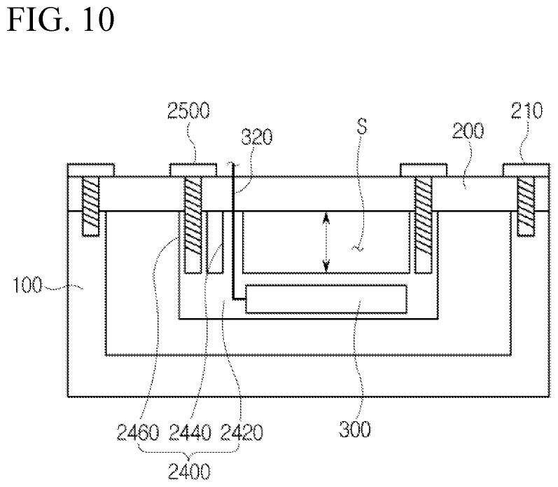

Next, an inverter according to a fifth embodiment of the present disclosure will be described with reference to FIG. 10.

The inverter according to the fifth embodiment of the present disclosure mainly includes the inverter housing 100, the printed circuit board (PCB) 200 coupled to the inverter housing 100, and a mechanism part 2400 on which the receiving element 300 is mounted. At this time, the mechanism part 2400 is provided between the inverter housing 100 and the printed circuit board 200, and the space part (S) is formed between the printed circuit board 200 and the mechanism part 2400.

Specifically, the inverter housing 100 has a E shape having the upper portion opened, and the printed circuit board 200 is coupled to the upper portion of the inverter housing 100. At this time, as a separate fastening means, for example, a bolt is fixed to the inverter housing 100 by penetrating the printed circuit board 200, the printed circuit board 200 may be coupled to the upper portion of the inverter housing 100.

In this embodiment, the mechanism part 2400 on which the receiving element 300 is mounted is coupled to the printed circuit board 200, and coupled in a state spaced apart from the printed circuit board 200.

For this purpose, the mechanism part 2400 includes a base 2420 on which the receiving element 300 is mounted, and a rib 2460 protruded and extended from the mechanism part 2400 toward the printed circuit board 200 is provided as a spacing means so that the mechanism part 2400 may be supported in a state spaced apart from the printed circuit board 200.

The rib 2460 is protruded and extended from the base 2420 to contact the print circuit board 200, and as a separate fastening means, for example, a bolt 2500 is fixed to the mechanism part 2400 through the rib 2460 by penetrating the printed circuit board 200, the base 2420 may be coupled in a state spaced apart from the printed circuit board 200.

Further, the lead 320 of the receiving element is inserted as a spacing means, and a lead inserting part 2440 extended from the mechanism part 2400 toward the printed circuit board 200 may be further provided. The lead inserting part 2440 may correspond to a portion of the rib 2460.

In this embodiment, the lead inserting part 2440 is protruded and extended from the base 2420 in parallel with the rib 2460 to contact the printed circuit board 200, and the lead 320 of the receiving element is soldered to the printed circuit board 200. The lead inserting part 2440 may be configured to insulate the lead 320 of the receiving element, and may serve to support the printed circuit board 200.

Likewise, the lead inserting part 2440 may be provided at the position corresponding to the position of the lead 320 of the receiving element 300 mounted on the mechanism part 2400.

As described above, as the receiving element 300 is connected to the printed circuit board 200 and at the same time, the space part (S) is secured between the printed circuit board 200 and the mechanism part 2400, a separate space for installing the mechanism part 2400 for mounting the receiving element 300 may not be required on the printed circuit board 200, thereby reducing the package of the inverter.

Further, various surface mounted devices mounted on the printed circuit board 200 may also be disposed on the space part (S), and a space where the surface mounted device may be disposed on the printed circuit board 200 is not limited, thereby freely disposing the element.

Likewise, the distance between the printed circuit board 200 and the mechanism part 2400 in the space part (S) is preferable formed larger than the maximum height of the surface mounted device protruded from the printed circuit board 200 in order to freely dispose the element.

Further, the present disclosure is not limited thereto but in this embodiment, the mechanism part 2400 is not only spaced apart from the printed circuit board 200 but also spaced apart from the inverter housing 100, such that it is effective for heat dissipation.

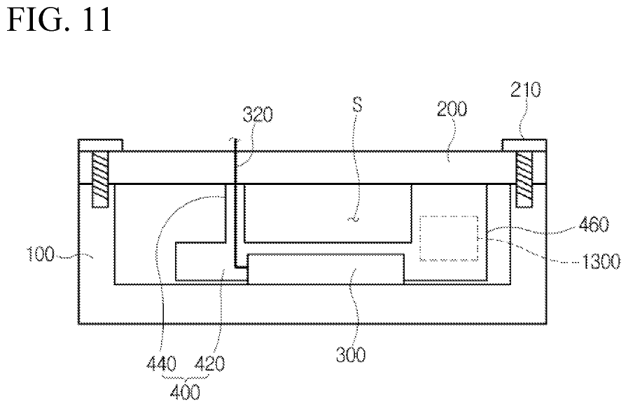

Finally, an inverter according to a sixth embodiment of the present disclosure will be described with reference to FIG. 11.

The inverter according to the sixth embodiment of the present disclosure mainly includes the inverter housing 100, the printed circuit board (PCB) 200 coupled to the inverter housing 100, and the mechanism part 400 on which the receiving element 300 is mounted. At this time, the mechanism part 400 is provided between the inverter housing 100 and the printed circuit board 200, and the space part (S) is formed between the printed circuit board 200 and the mechanism part 400.

The inverter housing 100 and the printed circuit board 200 are the same as those described in the first embodiment, and likewise, as the bolt 210 is fixed to the inverter housing 100 by penetrating the printed circuit board 200, the printed circuit board 200 may be coupled to the upper portion of the inverter housing 100.

However, in this embodiment, the mechanism part 400 in which the receiving element 300 is mounted is not a structure coupled to the housing 100 or the printed circuit board 200 through a separate fastening means as described above, and has different structure supported by contacting between the inverter housing 100 and the printed circuit board 200.

Specifically, a portion of the receiving element 300 may be protruded from the mechanism part 400 toward the inverter housing 100 side to contact the inverter housing 100. As described above, the receiving element 300 is in surface contact with the inverter housing 100, such that it is effective for heat dissipation. At this time, a seating groove in which the protruded receiving element 300 may be seated may also be formed in the inner surface of the inverter housing 100.

Accordingly, the base 420 of the mechanism part is spaced apart from the inverter housing 100, and the receiving element 300 partially protruded from the base 420 may be in surface contact with the inverter housing 100 and fixed thereto. In this embodiment, the receiving element 300 may be a capacitor.

Further, as a spacing means, the lead inserting part 440 and the rib 460 protruded and extended from the mechanism part 400 toward the printed circuit board 200 may be provided. Although the lead inserting part 440 is not different from those in the above embodiments, a separate fastening means is not penetrated and inserted into the rib 460 from the printed circuit board 200 as described above, and another receiving element 1300 may be disposed in the rib 460. For example, the receiving element disposed on the rib 460 may be a choke coil, etc.

The present disclosure is not limited to the above-described specific embodiment and description, and various modifications may be made by those skilled in the art to which the present disclosure pertains without departing from the subject matter of the present disclosure as claimed in the claims, and such modifications are within the scope of protection of the present disclosure.

What is claimed is:

1. An electric compressor, comprising:
an inverter housing;
a printed circuit board coupled to the inverter housing;
a mechanism part provided between the inverter housing and the printed circuit board and on which a receiving element is mounted; and
a spacing means for forming a space part between the printed circuit board and the mechanism part.

2. The electric compressor of claim 1, wherein the spacing means further comprises one or more ribs protruded and extended from the mechanism part toward the printed circuit board so that the mechanism part and the printed circuit board may be maintained in a state spaced apart from each other.

3. The electric compressor of claim 2, wherein at least one of the ribs is a lead inserting part into which a lead of the receiving element is inserted.

4. The electric compressor of claim 3, wherein the lead of the receiving element is soldered to the printed circuit board through the lead inserting part.

5. The electric compressor of claim 3, wherein the lead inserting part is provided at a position corresponding to a position of the lead of the receiving element mounted on the mechanism part.

6. The electric compressor of claim 2, wherein the mechanism part is coupled to the inverter housing.

7. The electric compressor of claim 6, wherein silicone is applied to a contact surface between the mechanism part and the inverter housing.

8. The electric compressor of claim 2, wherein the mechanism part is coupled to the printed circuit board.

9. The electric compressor of claim 2, wherein a portion of the receiving element is protruded from the mechanism part toward a side of the inverter housing to contact the inverter housing.

10. The electric compressor of claim 2, wherein a fastening means is fixed to the inverter housing by penetrating the printed circuit board.

11. The electric compressor of claim 2, wherein a fastening means is penetrated and inserted into at least one of the ribs from the printed circuit board.

12. The electric compressor of claim 1, wherein the receiving element is a passive element.

13. The electric compressor of claim 1, wherein the receiving element is a capacitor.

14. The electric compressor of claim 1, wherein a surface mounted device (SMD) is disposed on the printed circuit board in the space part between the printed circuit board and the mechanism part.

15. The electric compressor of claim 14, wherein a distance (h1) between the printed circuit board and the mechanism part is formed larger than a maximum height (h2) of the surface mounted device protruded from the printed circuit board in the space part.
